(19) United States
(12) Patent Application Publication
(10) Pub. No.: US 2005/0258467 A1
(43) Pub. Date: Nov. 24, 2005

(54) Nano-crystal non-volatile memory device employing oxidation inhibiting and charge storage enhancing layer

(75) Inventors: Shih-Wei Wang, Hsin Chu (TW); Hung-Cheng Sung, Hsin Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/851,841

(22) Filed: May 21, 2004

(51) Int. Cl. H01L 29/76

(52) U.S. Cl. 257/314

(57) ABSTRACT

A non-volatile memory device and a method for fabricating the non-volatile memory device employ at least one charge storage dot formed upon a substrate. At least one of an oxidation inhibiting layer and a charge storage enhancing layer is formed upon the charge storage dot. A silicon nitride material layer may simultaneously provide oxidation inhibiting properties and charge storage enhancing properties. The non-volatile memory device is formed with enhanced performance.

### BACKGROUND OF THE INVENTION

1. Field of the Invention

The invention relates generally to memory devices employed within semiconductor products. More particularly, the invention relates to non-volatile memory devices with enhanced performance, as employed within semiconductor products.

2. Description of the Relates Art

Memory cell structures are commonly employed as data storage components within integrated circuits. They may be broadly classified into the categories of volatile memory cell structures and non-volatile memory cell structures. Volatile memory cell structures require constant external electrical power in order to preserve data stored within volatile memory cell structures. In comparison, non-volatile memory cell structures are able to store charge even when the memory cell structure is not otherwise externally electrically powered. Non-volatile memory cell structures are often used for data storage within transiently operated consumer products such as digital cameras.

Non-volatile memory cell structures that employ nano-crystal quantum dot devices are currently of interest. Within such devices, a series of nano-crystal quantum dots serves as a floating gate electrode within a device structure that may otherwise resemble a dual gate electrically programmable memory device. The use of nano-crystal quantum dots as a floating gate electrode is desirable since charge leakage is reduced in comparison with a floating gate electrode formed as a single component.

Although nano-crystal quantum dot devices are desirable, they are nonetheless not entirely without problems. In particular, it is desirable to form such devices with enhanced performance. Enhanced performance is often related to enhanced data storage capabilities, which in turn are generally correlated with enhanced charge storage capabilities.

The invention is thus directed towards fabricating nano-crystal quantum dot devices with enhanced performance.

### SUMMARY OF THE INVENTION

A first object of the invention is to provide a non-volatile memory device for use within a semiconductor product.

A second object of the invention is to provide a non-volatile memory device in accord with the first object of the invention, wherein the non-volatile memory device has enhanced performance.

In accord with the objects of the invention, the invention provides a non-volatile memory device and a method for fabricating the non-volatile memory device.

In accord with the invention, the non-volatile memory device includes a substrate. At least one charge storage dot is formed upon the substrate. In addition at least one of an oxidation inhibiting layer and a charge storage enhancing layer is formed upon the at least one charge storage dot.

The invention provides a non-volatile memory device with enhanced performance for use within a semiconductor product.

The invention realizes the foregoing object within the context of a quantum dot type non-volatile memory device by employing at least one of an oxidation inhibiting layer and a charge storage enhancing layer formed upon the at least one charge storage dot within the non-volatile memory device. The at least one of the oxidation inhibiting layer and the charge storage enhancing layer provides for enhanced charge storage within the at least one charge storage dot, and thus enhanced performance within the non-volatile memory device.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3 and FIG. 4 show a series of schematic cross-sectional diagrams illustrating the results of progressive stages in forming a non-volatile memory device in accord with a preferred embodiment of the invention.

### DESCRIPTION OF THE PREFERRED EMBODIMENT

The invention provides a non-volatile memory device with enhanced performance for use within a semiconductor product.

The invention realizes the foregoing object within the context of a quantum dot type non-volatile memory device by employing at least one of an oxidation inhibiting layer and a charge storage enhancing layer formed upon at least one charge storage dot within the non-volatile memory device. The at least one of the oxidation inhibiting layer and the charge storage enhancing layer provides for enhanced charge storage within the at least one charge storage dot, and thus enhanced performance within the non-volatile memory device.

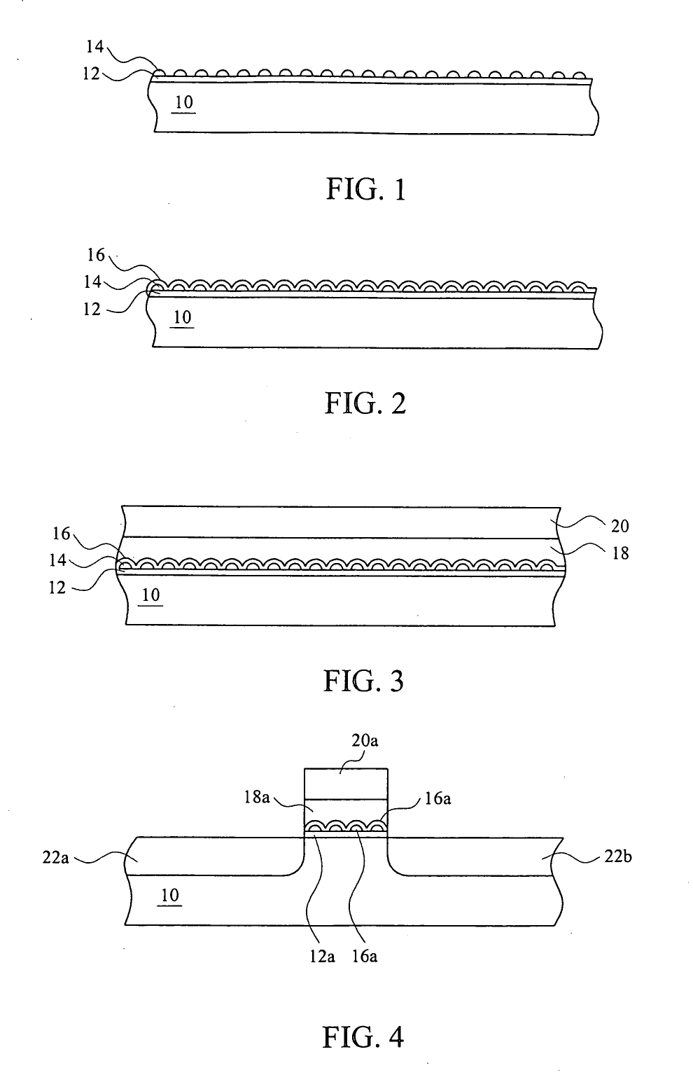

FIG. 1 to FIG. 4 show a series of schematic cross-sectional diagrams illustrating the results of progressive stages in forming a non-volatile memory device in accord with a preferred embodiment of the invention. FIG. 1 shows a schematic cross-sectional diagram of the non-volatile memory device at an early stage in its fabrication in accord with the preferred embodiment of the invention.

FIG. 1 shows a semiconductor substrate 10. A blanket gate dielectric layer 12 is formed upon the semiconductor substrate 10. A blanket discontinuous charge storage dot layer 14 is formed upon the blanket gate dielectric layer 12.

The semiconductor substrate 10 may be formed of semiconductor materials as are conventional in the semiconductor product fabrication art. Such semiconductor materials may include, but are not limited to, silicon semiconductor materials, germanium semiconductor materials, silicon-germanium alloy semiconductor materials and semiconductor-on-insulator semiconductor materials. Typically, the semiconductor substrate 10 is a silicon semiconductor substrate of appropriate dopant polarity, dopant concentration and crystallographic orientation.

The blanket gate dielectric layer 12 may be formed of a gate dielectric material as is otherwise generally conventional in the semiconductor product fabrication art. Such gate dielectric materials may include, but are not limited to silicon oxide gate dielectric materials, silicon nitride gate dielectric materials and fluorinated analogs thereof. (For reasons discussed in further detail below, the blanket gate dielectric layer 12 is preferably formed of a silicon nitride material or a fluorinated analog of a silicon oxide material or a silicon nitride material, rather than a silicon oxide material.) Typically, the blanket gate dielectric layer 12 is formed to a thickness of from about 30 to about 60 angstroms.

The blanket discontinuous charge storage dot layer 14 is typically formed of a discontinuous conductor material. The conductor material is typically formed in a discontinuous fashion while employing a deposition method that may be otherwise conventional in the semiconductor product fabrication art. The deposition method may provide for deposition for a comparatively short time period (i.e., from about 20 to about 30 seconds), such that individual charge storage dots are formed absent complete nucleation to form a contiguous layer. In the alternative, the deposition method may provide for forming a comparatively thin deposited layer that may be further thermally annealed and agglomerated to provide the blanket discontinuous charge storage dot layer 14. Deposition methods may include, but are not limited to chemical vapor deposition (CVD) methods and physical vapor deposition (PVD) methods. and tungsten materials. Typically, the blanket discontinuous charge storage dot layer 14 is formed of a surface coverage of from about 1E11 to about 1E12 dots per square centimeter surface area. Individual discontinuous charge storage dots typically have a circular diameter of from about to about angstroms and a height of from about to about angstroms.

FIG. 2 shows the results of forming a blanket oxidation inhibiting and charge storage enhancing layer 16 upon the blanket discontinuous charge storage dot layer 14 of FIG. 1. The invention provides value under circumstances where at least either an oxidation inhibiting layer or a charge storage enhancing layer is formed upon the blanket discontinuous charge storage dot layer 14. However, from a practical perspective within the invention, a silicon nitride or silicon nitride containing material may be employed for providing both oxidation inhibiting properties and charge storage enhancing properties when forming the blanket oxidation inhibiting and charge storage enhancing layer 16. Such silicon nitride materials provide for superior charge trapping at a charge storage dot interface in comparison with a silicon oxide material that is not preferred within the context of the invention. Typically, the blanket oxidation inhibiting and charge storage enhancing layer 16 is formed of silicon nitride material formed to a thickness of from about 10 to about 40 angstroms.

FIG. 3 first shows a blanket control dielectric layer 18 formed upon the blanket oxidation inhibiting and charge storage enhancing layer 16. FIG. 3 also shows a blanket gate electrode material layer 20 formed upon the blanket control dielectric layer 18.

The blanket control dielectric layer 18 is typically formed of a silicon oxide dielectric material formed to an appropriate thickness such as to optimize performance of the non-volatile memory device of the invention. The blanket control dielectric layer 18 thickness typically influences or determines a threshold voltage of a non-volatile memory device. Typically, the thickness is in a range of from about 50 to about 80 angstroms.

The blanket control gate electrode material layer 20 is typically formed of a doped polysilicon material formed to a thickness of from about 1500 to about 2500 angstroms.

FIG. 4 first shows the results of sequentially patterning: (1) the blanket control gate electrode material layer 20; (2) the blanket control dielectric layer 18; (3) the blanket oxidation inhibiting and charge storage enhancing layer 16; (4) the blanket discontinuous charge storage dot layer 14; and (5) the blanket gate electrode material layer 12. The patterning forms a corresponding series including: (1) a patterned gate electrode material layer 20a; (2) a patterned control dielectric layer 18a; (3) a patterned oxidation inhibiting and charge storage enhancing layer 16a; (4) a patterned discontinuous charge storage dot layer 14a; and (5) a patterned gate dielectric layer 12a. The foregoing patterning is typically undertaken employing a masked anisotropic plasma etching employing a patterned mask layer that is not otherwise illustrated.

FIG. 4 also shows a pair of source/drain regions 22a and 22b formed into the semiconductor substrate 10 while employing the series of patterned layers 12a/14a/16a/18a/20a as a mask. The pair of source/drain regions 22aand 22b is formed employing an ion implanting of a dopant of appropriate polarity and concentration into the semiconductor substrate 10.

FIG. 4 shows a schematic cross-sectional diagram of a non-volatile memory device in accord with the invention. The non-volatile memory device is formed within the context of a nano-crystal quantum dot non-volatile memory device having a series of charge storage dots interposed between a tunneling dielectric layer and a control dielectric layer. An oxidation inhibiting and charge storage enhancing layer is formed upon the discontinuous charge storage dot layer, although the invention provides value within the context of either one of an oxidation inhibiting layer and a charge storage enhancing layer. The oxidation inhibiting character of the layer inhibits oxidation of individual charge storage dots within the discontinuous charge storage dot layer, thus enhancing charge storage character thereof. The charge storage enhancing character of the layer provides for enhanced performance incident to enhancing charge that may be stored within the individual charge storage dots.

The preferred embodiment of the invention is illustrative of the invention rather than limiting of the invention. Revisions and modifications may be made to methods, materials, structures and dimensions in accord with the preferred embodiment of the invention while still providing an embodiment in accord with the invention, further in accord with the accompanying claims.

1. A non-volatile memory device comprising:
a substrate;
at least one charge storage dot formed upon the substrate;
at least one of an oxidation inhibiting layer and a charge storage enhancing layer formed upon the at least one charge storage dot.

2. The device of claim 1 wherein the substrate comprises a tunneling dielectric layer formed upon a semiconductor substrate.

3. The device of claim 1 wherein the at least one charge storage dot is formed from a material selected from the group consisting of silicon, germanium, silicon-germanium alloy and tungsten materials.

4. The device of claim 1 wherein a silicon nitride material layer is employed as both an oxidation inhibiting layer and a charge storage enhancing layer.

5. The device of claim 4 wherein the silicon nitride material layer is formed to a thickness of from about 10 to about 40 angstroms.

6. The device of claim 2 further comprising:
a patterned control dielectric layer formed aligned upon the at least one of the oxidation inhibiting layer and charge storage enhancing layer as a patterned layer;
a gate electrode formed aligned upon the patterned control dielectric layer; and
a pair of source/drain regions formed into the semiconductor substrate and spaced by(? It seems improper.) the gate electrode.

7. A non-volatile memory device comprising:
a semiconductor substrate;
a tunneling dielectric layer formed upon the semiconductor substrate;
a patterned discontinuous charge storage dot layer formed upon the tunneling dielectric layer;
at least one of a patterned oxidation inhibiting layer and a patterned charge storage enhancing layer formed aligned upon the patterned discontinuous charge storage dot layer;
a control gate electrode aligned over the at least one of the patterned oxidation inhibiting layer and the patterned discontinuous charge storage dot layer; and
a pair of source/drain regions formed into the semiconductor substrate at areas not covered by the control gate electrode.

8. The device of claim 7 wherein the semiconductor substrate is formed from a semiconductor material selected from the group 67,200-1277 2003-1580 consisting of silicon, germanium, silicon-germanium alloy and semiconductor-on-insulator semiconductor materials.

9. The device of claim 7 wherein the tunneling dielectric layer is formed of a silicon oxide material.

10. The device of claim 7 wherein the patterned discontinuous charge storage dot layer employs charge storage dots formed from a material selected from the group consisting of silicon, germanium, silicon-germanium alloy and tungsten materials.

11. The device of claim 7 wherein a patterned silicon nitride material layer is employed as both the patterned oxidation inhibiting layer and the patterned charge storage enhancing layer.

12. The device of claim 11 wherein the silicon nitride material layer is formed to a thickness of from about 10 to about 40 angstroms.

13. The device of claim 7 wherein the control gate electrode is formed of a polysilicon material.

14. A method for fabricating a non-volatile memory device comprising:
providing a substrate;
forming at least one charge storage dot upon the substrate; and
forming at least one of an oxidation inhibiting layer and a charge storage enhancing layer upon the at least one charge storage dot layer.

15. The method of claim 14 wherein the substrate comprises a tunneling dielectric layer formed upon a semiconductor substrate.

16. The method of claim 14 wherein the at least one charge storage dot is formed from a material selected from the group consisting of silicon, germanium, silicon-germanium alloy and tungsten materials.

17. The method of claim 14 wherein a silicon nitride material layer is employed as the oxidation inhibiting layer and the charge storage enhancing layer.

18. The method of claim 17 wherein the silicon nitride material layer is formed to a thickness of from about 10 to about 40 angstroms.

19. The method of claim 15 further comprising:
forming a patterned control dielectric layer aligned upon the at least one of the oxidation inhibiting layer and the charge storage enhancing layer as a patterned layer;
forming a gate electrode upon the patterned control dielectric layer; and
forming a pair of source/drain regions into the semiconductor substrate and spaced by the gate electrode.

20. The method of claim 19 wherein the gate electrode is formed of a polysilicon material.
